(19) United States
(12) Patent Application Publication
(10) Pub. No.: US 2011/0228503 A1
(43) Pub. Date: Sep. 22, 2011

(54) POWER STRUCTURE

(75) Inventor: Shao-Feng Lu, Taoyuan County (TW)

(73) Assignees: FSP TECHNOLOGY INC., Taoyuan County (TW); 3Y POWER TECHNOLOGY (TAIWAN), INC., Taoyuan County (TW)

(21) Appl. No.: 12/727,250

(22) Filed: Mar. 19, 2010

(51) Int. Cl. H05K 1/14

(52) U.S. Cl. 361/803

(57) ABSTRACT

A power structure including a circuit board, a power transforming circuit board, and a fixing element is provided. The circuit board includes a substrate, a set of power supply connector, and a first power output structure. The set of power supply connector and the first power output structure are electrically connected. The first power output structure has a first fixing hole and at least one cable connecting hole. The power transforming circuit board has a power input structure and at least one power transforming circuit. The power input structure having a second fixing hole is electrically connected to the power transforming circuits. The fixing element penetrates through the first fixing hole of the first power output structure and the second fixing hole of the power input structure, so as to electrically connect the first power output structure to the power input structure.

### BACKGROUND OF THE INVENTION

1. Field of the Invention

The present invention relates to a power structure. More particularly, the present invention relates to a power structure different to a conventional power structure.

2. Description of Related Art

Generally, power supply is an important element in an electronic device that is used for power transforming. With a continuous development of electronic technology, Internet and multimedia techniques gradually become mature. Therefore, the power supply capable of providing a stable power output is highly required. Since a design cost and a technique level of a high-power power supply are relatively high, multi-level power supplies formed through a stacking or a parallel approach are provided, and the multi-level power supplies can be further grouped into parallel power supplies and redundant power supplies having high-power output.

FIG. 1 is a schematic diagram illustrating a circuit board used to electrically connect a conventional multi-level power supply. Referring to FIG. 1, the circuit board 10 has a plurality sets of power connectors 11a and 11b for electrically connecting a plurality of power supplies 40, each set of the power connectors 11a and 11b is electrically connected to power processing circuits 12a and 12b, and a cooling hole 13 is configured between each set of the power connectors 11a and 11b. Moreover, a lower part of the circuit board 10 has a power transforming circuit 14. The power processing circuits 12a and 12b can integrate power through power bridges 20, and power lines 30 are connected to power connection holes 14a on the power transforming circuit 14. Since the output power required by the electronic devices is gradually increased, though the electronic device, for example, a 2U or a 3U server has to satisfy a current fixed industrial specification (the so-called 2U or 3U is an industrial specification of a standard definition of a width of 10 inches and a height of 1.75 inches), and also the circuit board 10 has to be configured with the power transforming circuit 14, an amount of the power connectors 11a and 11b on the circuit board 10 is limited, which may cause a waste of space. Moreover, since voltage powers output by various electronic devices are different, once an amount of the power lines 30 required to be connected exceeds an amount of the power connection holes 14a on the power transforming circuit 14, the circuit board cannot be expended for using, which may cause a utilization trouble.

### SUMMARY OF THE INVENTION

The present invention is directed to a power structure different from a conventional power structure.

The present invention provides a power structure including a circuit board, a power transforming circuit board, and a fixing element. The circuit board includes a substrate, a set of power supply connector, and a first power output structure. The set of power supply connector and the first power output structure are electrically connected. The first power output structure has a first fixing hole and at least one cable connecting hole. The power transforming circuit board has a power input structure and at least one power transforming circuit. The power input structure having a second fixing hole is electrically connected to the power transforming circuits. The fixing element penetrates through the first fixing hole of the first power output structure and the second fixing hole of the power input structure, so as to electrically connect the first power output structure of the circuit board to the power input structure of the power transforming circuit board.

In an embodiment of the present invention, the circuit board has a ground part.

In an embodiment of the present invention, the first power output structure is welded on the substrate.

In an embodiment of the present invention, the power input structure further has at least one cable connecting hole.

In an embodiment of the present invention, the power transforming circuit board further includes at least one second power output structure disposed aside the power input structure, and each of the second power output structures is electrically connected to one of the power transforming circuits.

In an embodiment of the present invention, the power structure further includes at least one power line, and the power lines are suitable for being inserted to the cable connecting holes of the first power output structure, the second power output structure or the power input structure.

In an embodiment of the present invention, the power supply connector and the first power output structure are respectively disposed on two opposite surfaces or a same surface of the substrate.

According to the above descriptions, the power structure of the present invention is different to a conventional power structure. The circuit board and the power transforming circuit board respectively have the power output structures, and the power output structures have at least one cable connecting hole, so that different to a conventional technique that the cable connecting holes are configured on the circuit board, sizes of the circuit board and the power transforming circuit board of the present invention can be reduced.

In order to make the aforementioned and other features and advantages of the present invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a circuit board used to electrically connect a conventional multi-level power supply.

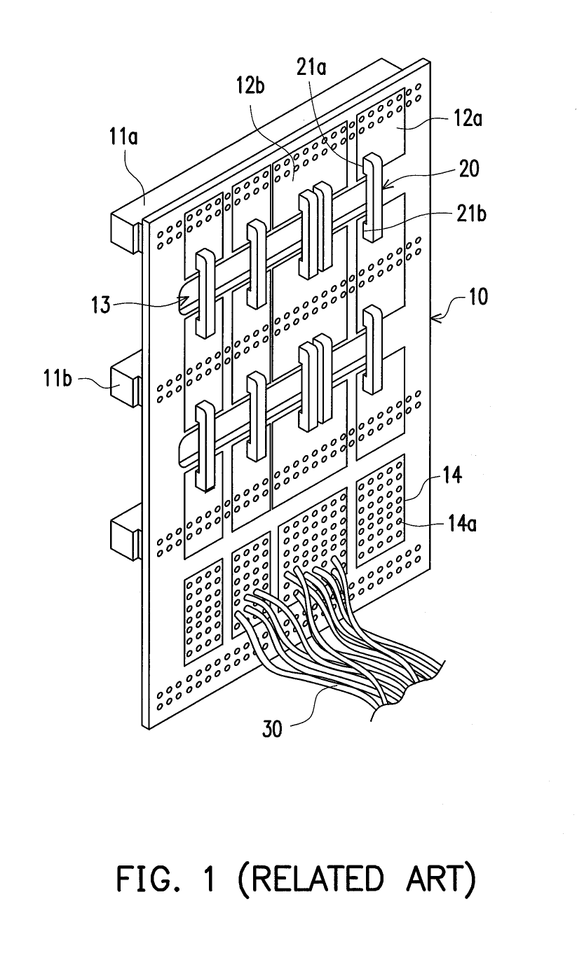

FIG. 2 is a schematic diagram illustrating a power structure according to an embodiment of the present invention.

FIG. 3 is a schematic diagram illustrating a situation that a power supply connector and a first power output structure are disposed at a same surface of a substrate.

### DESCRIPTION OF THE EMBODIMENTS

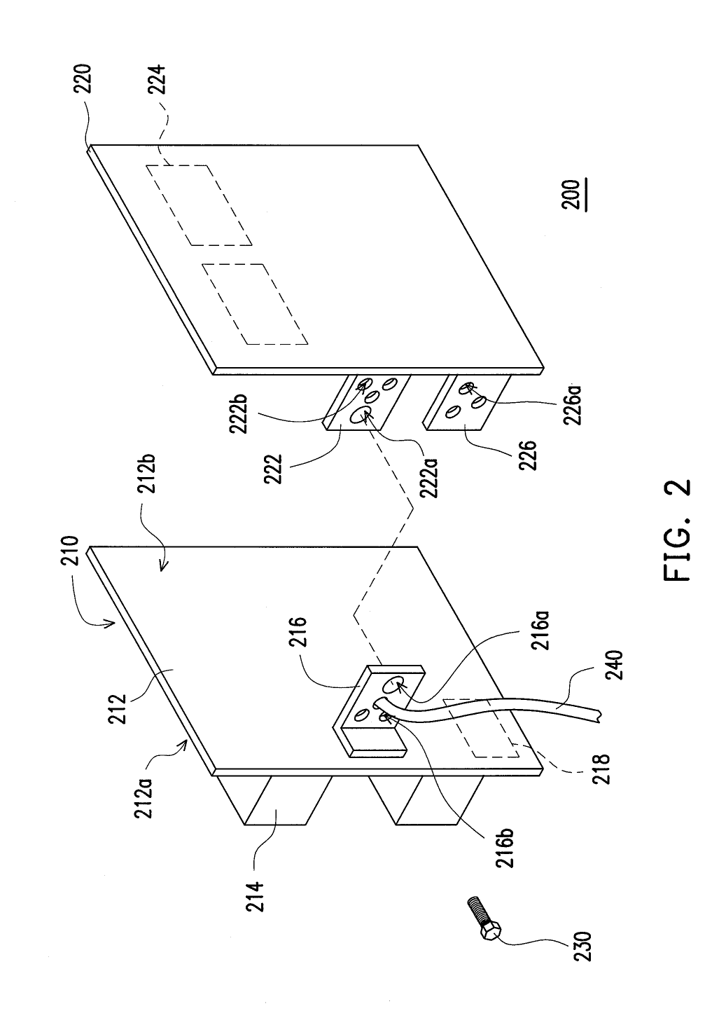

FIG. 2 is a schematic diagram illustrating a power structure according to an embodiment of the present invention. Referring to FIG. 2, the power structure 200 of the present embodiment includes a circuit board 210, a power transforming circuit board 220, and a fixing element 230. The circuit board 210 includes a substrate 212, a set of power supply connector 214, and a first power output structure 216. The set of power supply connector 214 and the first power output structure 216 are electrically connected. The first power output structure 216 has a first fixing hole 216a and at least one cable connecting hole 216b. The power transforming circuit board 220 has a power input structure 222 and at least one power transforming circuit 224. The power input structure 222 having a second fixing hole 222a is electrically connected to the power transforming circuit 224. The fixing element 230 penetrates through the first fixing hole 216a of the first power output structure 216 and the second fixing hole 222a of the power input structure 222, so as to electrically connect the first power output structure 216 of the circuit board 210 with the power input structure 222 of the power transforming circuit board 220. A whole size of the circuit board 210 and the power transforming circuit 220 of the power structure 200 is smaller than that of a conventional power structure.

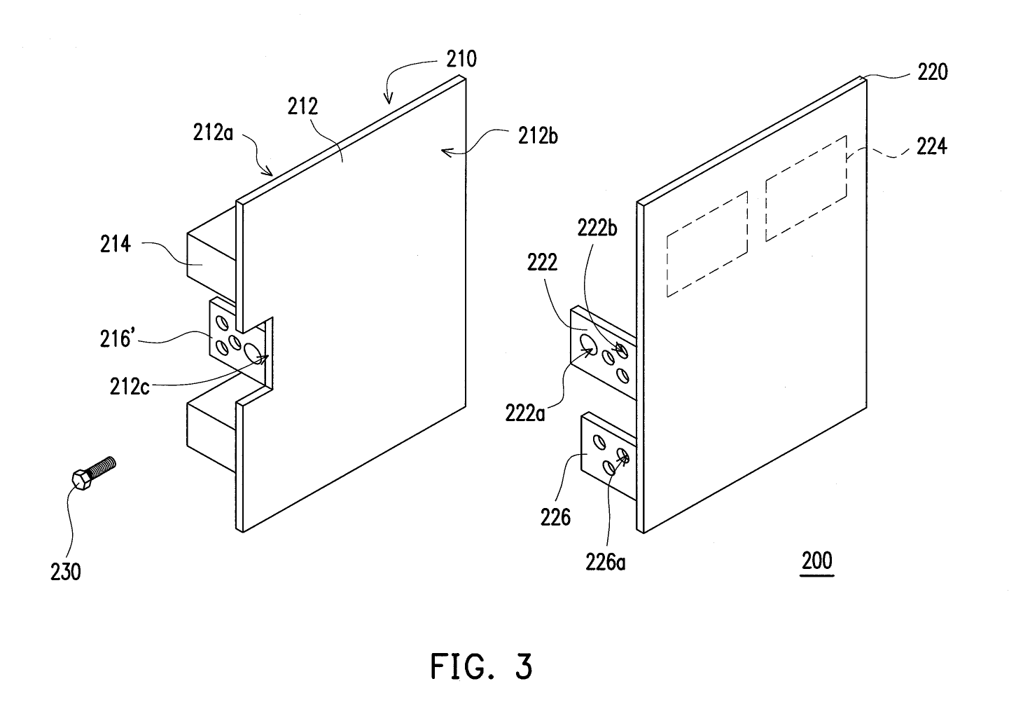

According to the above description, the power supply connector 214 and the first power output structure 216 can be disposed on two opposite surfaces 212a and 212b of the substrate 212. FIG. 3 is a schematic diagram illustrating a situation that a power supply connector and a first power output structure are disposed at a same surface of the substrate. Referring to FIG. 3, in this embodiment, the first power output structure 216′ and the power supply connector 214 can be disposed on the same surface 212a of the substrate 212, wherein the substrate 212 has a recession structure 212c to facilitate assembling the power input structure 222 to the first power output structure 216′.

Referring to FIG. 2 again, the power supply connector 214 is connected to a power supply (not shown), so that power of the power supply can be output through the power structure 200 of the present embodiment. The first power output structure 216 is welded on the substrate 212. Similarly, the power input structure 222 can also be welded on a substrate (not marked) of the power transforming circuit board 220, and the first power output structure 216 of the circuit board 210 and the power input structure 222 of the power transforming circuit board 220 are mutually faced to facilitate assembling. Though the assembling approach of welding is taken as an example in the present embodiment, those skilled in the art can also change the assembling approach of assembling the first power output structure 216 to the substrate 212 and assembling the power input structure 222 to the substrate (not marked) of the power transforming circuit board 222 according to an actual demand, for example, fastening, buckling or other suitable approaches.

Moreover, the power transforming circuit board 220 further has at least one second power output structure 226 disposed aside the power input structure 222, and each of the second power output structures 226 is electrically connected to one of the power transforming circuits 224. As shown in FIG. 2, the second power output structure 226 and the power input structure 222 are located on a same surface, though in another embodiment that is not illustrated, the second power output structure 226 and the power input structure 222 can also be disposed on different surfaces according to an actual demand.

Referring to FIG. 2 again, the power input structure 222 and the second power output structure 226 has a plurality of cable connecting holes 222b and 226a (or only one cable connecting hole is configured according to a design requirement), and the power structure 200 further includes at least one power line 240. When there is a plurality of the power lines 240, the power lines 240 can be respectively inserted into the cable connecting holes 216b, 226a and 222b of the first power output structure 216, the second power output structure 226 and the power input structure 222.

When the power structure 200 of the present embodiment is used, the fixing element 230 (for example, a screw) penetrates through the first fixing hole 216a of the first power output structure 216 of the circuit board 210, and is locked into the second fixing hole 222a of the power input structure 222 of the power transforming circuit board 220, so that the circuit board 210 and the power transforming circuit 220 are fixed and electrically connected. It should be noticed that the first power output structure 216 on the substrate 210 has at least one cable connecting hole 216b, so that the power line 240 can be directly inserted into the cable connecting hole 216b, and therefore the power provided by the power supply connector 214 can be directly output without transformation. In other words, if the power provided by the power supply connected to the power supply connector 214 is 12 volts, an output power of the power line 240 connected to the cable connecting hole 216b is also 12 volts.

According to the above descriptions, by electrically connecting the first power output structure and the power input structure 222 (the so-called “electrically connecting” refers to that the first power output structure 216 and the power input structure 222 can be directly connected or can be electrically connected through the fixing element 230 serving as a conductor), the power of the power supply connected to the power supply connector 214 can be transmitted to the power transforming circuit board 220. Moreover, the power line 240 can also be inserted into the cable connecting hole 222b of the power input structure 222 locked and electrically connected with the first power output structure 216. Now, since the power is not transformed, the power output by the power line 240 and the power output by the first power output structure 216 are the same. By configuring a plurality of the cable connecting holes 222b on the power input structure 222 to connect the power lines 240, power output extendibility can be increased.

Referring to FIG. 2 again, based on a transformation of the power transforming circuit 224, the power output by the second power output structure 226 electrically connected to the individual power transforming circuit 224 can be different. For example, based on the transformation of the power transforming circuit 224, the power output by the second power output structure 226 can be 5 volts. It should be noticed that the power transforming circuit board 220 has a plurality of the power transforming circuits 224, so that the second power output structures 226 electrically connected to the power transforming circuits 224 are also plural, though only one second power output structure 226 is illustrated in FIG. 2 for simplicity's sake. The output power transformed by the power transforming circuits 224 can be different. In other words, the output power of a plurality of the second power output structures 226 can be the same, and the output power of a plurality of the other second power output structures 226 can be different.

Compared to the conventional structure, the substrate 212 of the circuit board 210 of the present embodiment is not configured with the power transforming circuit and the cable connecting hole, so that a usage area of the substrate 212 can be effectively reduced. Moreover, the power transforming circuits 224 are disposed on the power transforming circuit board 220, and the power transforming circuit board 220 is not configured with the cable connecting hole, so that a usage area of the power transforming circuit board 220 can be effectively reduced. Due to a configuration of the power input structure 222, the second power output structures 226 and the cable connecting holes 222b and 226a configured thereon, the power can still be output through the power lines 240, so that the power structure 200 can be normally used. Alternatively, in case that a size of the conventional circuit board is not changed, a layout of the power transforming circuit can be more flexible. The above advantages of the power structure can be determined according to a demand of a user, and can be implemented by changing a structure design.

Moreover, to prevent static power or generation of abnormal large current that probably causes a damage of the power structure 200, and prevent the user from an electric shock, the circuit board 210 may have a ground part 218. Similarly, the power transforming circuit board 220 can also be configured with a ground part (not shown), which can be determined by the user according to an actual requirement.

In summary, the power structure of the present invention is different to a conventional power structure. Moreover, compared to the conventional structure, sizes of the circuit board and the power transforming circuit board of the power structure of the present invention can be effectively reduced, so that design features of lightness, slimness, shortness and smallness of an electronic device using such power structure can be achieved, so as to match a demand of the user. Alternatively, in case that a size of the power transforming circuit board is maintained the same as that of the conventional power structure, a layout of the power transforming circuit can be more flexible. Therefore, the power structure of the present invention has patentability.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A power structure, comprising:
a circuit board, comprising a substrate, a set of power supply connector, and a first power output structure, the set of power supply connector and the first power output structure being electrically connected, and the first power output structure having a first fixing hole and at least one cable connecting hole;
a power transforming circuit board, having a power input structure and at least one power transforming circuit, wherein the power input structure has a second fixing hole, and the power input structure is electrically connected to the power transforming circuits; and
a fixing element, penetrating through the first fixing hole of the first power output structure and the second fixing hole of the power input structure, so as to electrically connect the first power output structure of the circuit board with the power input structure of the power transforming circuit board.

2. The power structure as claimed in claim 1, wherein the circuit board has a ground part.

3. The power structure as claimed in claim 1, wherein the first power output structure is welded on the substrate.

4. The power structure as claimed in claim 1, further comprising at least one power line, and the power lines being inserted to the cable connecting holes of the first power output structure.

5. The power structure as claimed in claim 1, wherein the power input structure further has at least one cable connecting hole.

6. The power structure as claimed in claim 5, further comprising at least one power line, and the power lines being inserted to the cable connecting holes of the power input structure.

7. The power structure as claimed in claim 1, wherein the power transforming circuit board further comprises at least one second power output structure disposed aside the power input structure, and each of the second power output structures being electrically connected to one of the power transforming circuits.

8. The power structure as claimed in claim 7, further comprising at least one power line, wherein the second power output structure has at least one cable connecting holes, and the at least one power line is inserted to the at least one cable connecting hole of the second power output structure.

9. The power structure as claimed in claim 1, wherein the power supply connector and the first power output structure are respectively disposed on two opposite surfaces of the substrate.

10. The power structure as claimed in claim 1, wherein the power supply connector and the first power output structure are disposed on a same surface of the substrate.
